(19) United States
(12) Patent Application Publication
(10) Pub. No.: US 2002/0034867 A1
(43) Pub. Date: Mar. 21, 2002

(54) Method for manufacturing self-aligned silicide layer

(76) Inventors: Chi-Tung Huang, Hsinchu (TW); Cheng-Chen Hsueh, Taipei (TW)

Correspondence Address: J C Patents, 4 Venture, Suite 250, Irvine, CA, 92618, US

(21) Appl. No.: 09/546,082

(22) Filed: Apr. 10, 2000

(51) Int. Cl. H01L 21/3205; H01L 21/4763; H01L 21/461; H01L 21/336

(52) U.S. Cl. 438/592; 438/683; 438/719

(57) ABSTRACT

A method for forming a self-aligned silicide layer. A substrate having an MOS formed thereon is provided. A reduction reaction is performed. A metal layer is formed over the substrate. A silicification is performed to convert portions of the metal layer into a self-aligned silicide layer. Another portion of the metal layer that is not converted into the self-aligned silicide layer is removed.

### BACKGROUND OF THE INVENTION

1. Field of Invention

The present invention relates to a method for manufacturing a semiconductor. More particularly, the present invention relates to a method for manufacturing a self-aligned silicide layer.

2. Description of Related Art

Typically, the method for forming a salicide layer comprises a step of forming a metal layer on the semiconductor wafer. Usually, the metal layer is made of titanium, cobalt or nickel. After that, the wafer is disposed in a high temperature environment so that the portion of the metal layer contacting the silicon material is converted into the silicide with a relatively small resistance. On the other hand, the silicide is not formed on the portion of the wafer where the metal layer is not directly in contact with the silicon material. Therefore, the silicide formed on the particular site without performing any photolithography process is called self-aligned silicide (salicide).

However, it is easily to form a native oxide layer on the surface of the semiconductor wafer in the semiconductor manufacturing process. The native oxide layer suppresses the formation of the salicide and decreases the conductive performance of the salicide formed subsequently. Therefore, a pre-cleaning process is usually performed to remove the native oxide layer or impurities on the semiconductor wafer before the metal layer is formed. The result of the pre-cleaning process affects the quality of the salicide formed subsequently. Conventionally, the pre-cleaning process is a wet etching process, that is, dipping the semiconductor wafer into an etchant. Thereafter, the semiconductor wafer is dried. After the drying process, a physical bombardment plasma treatment with an argon plasma is performed to remove the native oxide layer by physical bombardment.

Nevertheless, only using wet etching as a pre-cleaning process easily leads to the re-formation of the native oxide layer on the semiconductor wafer. Additionally, the physical-bombardment plasma treatment on the semiconductor wafer easily causes defects and charge accumulation on the surface of the semiconductor wafer. Hence, the devices formed in the semiconductor are damaged and the yield is decreased.

### SUMMARY OF THE INVENTION

The invention provides a pre-cleaning process performed on a substrate before a salicide process is performed. A reactive plasma treatment process is performed to perform a reduction reaction on the substrate, wherein the reactive plasma treatment process comprises a reactive plasma.

The invention also provides a method for forming a salicide layer. A substrate having an MOS formed thereon is provided. A reduction reaction is performed. A metal layer is formed over the substrate. A silicification is performed to convert portions of the metal layer into a salicide layer. Another portion of the metal layer that is not converted into the salicide layer is removed.

As embodied and broadly described herein, the step of reduction reaction includes a reactive plasma treatment process. The reactive plasma treatment process comprises a reactive gas-containing plasma, such as hydrogen plasma.

In the present invention, since the reduction reaction is performed before the salicide process is performed, the native oxide layer over the substrate is reduced for removal and the surface of the substrate is cleaned. The problem of re-formation of the native oxide after the typically wet etching cleaning process is performed can be overcome. Additionally, the native oxide layer is removed by chemical reaction so that substrate surface damage caused by the physical bombardment can be avoided. Hence, the problems of damaged devices and the decreasing yield can be solved. Furthermore, the efficacy of the devices can be greatly increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1C are schematic, cross-sectional views of the process for manufacturing a salicide in a preferred embodiment according to the invention; and

FIG. 2 is a flowchart of the pre-cleaning process in the preferred embodiment according to the invention.

### DESCRIPTION OF THE PREFERRED EMBODIMENTS

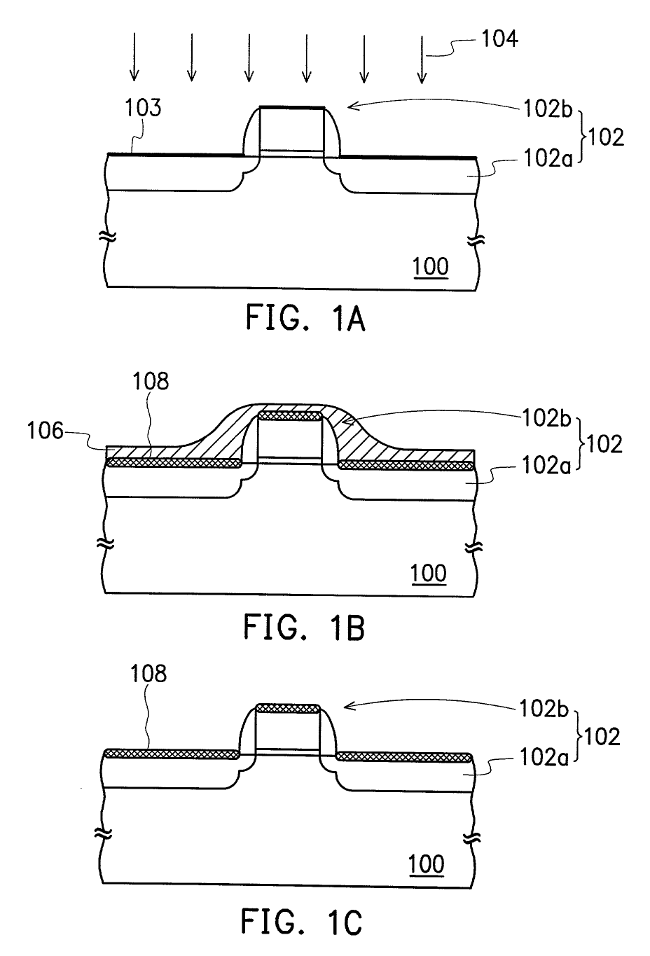

FIGS. 1A through 1C are schematic, cross-sectional views of the process for manufacturing a salicide in a preferred embodiment according to the invention.

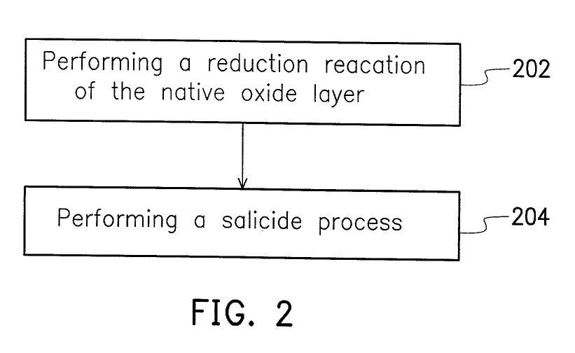

FIG. 2 is a flowchart of the pre-cleaning process in the preferred embodiment according to the invention.

As shown in FIG. 1A together with FIG. 2, a substrate 100 having an MOS 102 formed thereon is provided. The MOS 102 comprises a source/drain region 102a formed in the substrate 100 and a gate structure 102b formed on the substrate 100. With the manufacturing process, a native oxide layer 103 is formed on the source/drain region 102a and the top surface of the gate structure 102b.

Before the salicide is formed, a pre-cleaning process is performed to remove the impurities and the native oxide layer 103 over the substrate 100. The pre-cleaning process comprises a reactive plasma treatment process with a reactive plasma 104. Based on the chemical reaction, the reduction reaction 202 (as shown in FIG. 2) is performed between the reactive plasma 104 and the native oxide layer 103 and the native oxide 103 is removed during the reduction reaction 202. The reactive plasma 104 can be a reductive gas-containing plasma, for example. Preferably, the reductive gas-containing plasma can be hydrogen plasma. Reactive plasma formation methods include radio frequency process, microwave process and thermal process, for example. Additionally, the pre-cleaning process further comprises a wet etching cleaning process before the reactive plasma treatment process is performed.

Since the reactive plasma treatment process is performed before the process for forming the salicide is performed, the reduction reaction is performed between the native oxide layer 103 and the reactive plasma 104 until the native oxide layer 103 is removed and the surface of the substrate 100 is cleaned. Because the native oxide layer 103 is removed by chemical reaction, substrate surface damage can be avoided. Therefore, after the traditional wet etching process as a pre-cleaning process is performed, contamination on the substrate 100 due to the re-formation of the native oxide can be avoided. Moreover, the problem of the surface damage caused by the physical bombardment used to remove the native oxide layer can be overcome. Hence, the problems of damaged devices and the decreasing yield can be solved. Furthermore, the efficacy of the devices can be greatly increased.

As shown in FIG. 1B together with FIG. 2, a salicide process 204 is performed. The salicide process 204 comprises the step of forming a metal layer 106 over the substrate 100. The metal layer 106 is made of refractory metal, for example. The refractory metal includes titanium, tungsten, cobalt, nickel, platinum or palladium, for example. The method of forming the metal layer 106 can be performed by a conventional method known to the skilled in the art. A thermal process is performed and a silicification occurs at the interface between the metal layer 106 and gate electrode 102b and the source/drain region 102a. Therefore, portions of the metal layer 106 above the gate electrode 102b and the source/drain region 102a are converted into a salicide layer 108. The salicide layer 108 can be a titanium nitride layer, for example. The thermal process is performed in a temperature about 400-750° C.

As shown in FIG. 2C, the remaining metal layer 106, which is not converted into the salicide layer 108, is removed to expose the salicide layer 108. The method of removing the metal layer 106 can be a conventional method known to the skilled in the art. In this example, the metal layer is removed by wet etching. A thermal process is performed to finish the salicide process. The thermal process is performed in a temperature about 650-900° C.

In the present invention, since the reactive plasma treatment process is performed before the salicide process is performed, the reduction reaction is performed between the native oxide layer 103 and the reactive plasma 104 until the native oxide layer 103 is reduced to be removed and the surface of the substrate 100 is cleaned. The native oxide layer 103 is removed by chemical reaction so that substrate surface damage caused by the physical bombardment can be avoided. Hence, the problems of damaged devices and the decreasing yield can be solved. Furthermore, the efficacy of the devices can be greatly increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A pre-cleaning process performed on a substrate before salicide process is performed, comprising the steps of:
performing a reactive plasma treatment process to perform a reduction reaction on the substrate, wherein the reactive plasma treatment process comprises a reactive plasma.

2. The pre-cleaning process of claim 1, wherein the reactive plasma includes a reductive gas-containing plasma.

3. The pre-cleaning process of claim 2, wherein the reductive gas-containing plasma is formed by a thermal process.

4. The pre-cleaning process of claim 2, wherein the reductive gas-containing plasma is formed by a radio frequency process.

5. The pre-cleaning process of claim 2, wherein the reductive gas-containing plasma is formed by a microwave process.

6. The pre-cleaning process of claim 1, wherein the reactive plasma treatment process includes a hydrogen plasma.

7. A method for forming a salicide layer, comprising the steps of:
providing a substrate having an MOS formed thereon;
performing a reduction reaction;
forming a metal layer over the substrate;
performing a silicification to convert portions of the metal layer into a salicide layer; and
removing another portion of the metal layer not converted into the salicide layer.

8. The method of claim 7, wherein the step of performing the reduction reaction includes a reactive plasma treatment process.

9. The method of claim 8, wherein the reactive plasma treatment includes a reductive gas-containing plasma.

10. The method of claim 9, wherein the reductive gas-containing plasma is formed by a thermal process.

11. The method of claim 9, wherein the reductive gas-containing plasma is formed by a radio frequency process.

12. The method of claim 9, wherein the reductive gas-containing plasma is formed by a microwave process.

13. The method of claim 8, wherein the reactive plasma treatment process includes a hydrogen plasma.

14. The method of claim 7, wherein a metal for the metal layer is chosen from a group consisting of titanium, tungsten, cobalt, nickel, platinum and palladium.

15. The method of claim 7, wherein the step of performing the silicification includes a thermal process.

16. The method of claim 15, wherein a temperature of the thermal process is about 450-750° C.

17. The method of claim 7, further comprising a step of performing a wet etching process before the reduction reaction is performed.
